(19) United States
(12) Patent Application Publication
(10) Pub. No.: US 2011/0098954 A1
(43) Pub. Date: Apr. 28, 2011

(54) Feedback Mechanism for Scanner

(76) Inventors: Rainer Falk, Erding (DE); Ulrike Meyer, Aachen (DE)

(21) Appl. No.: 12/996,916

(22) PCT Filed: Jun. 13, 2008
(86) PCT No.: PCT/EP08/04774

§ 371 Date: Dec. 8, 2010

(51) Int. Cl. G06F 19/00; G01R 21/00

(52) U.S. Cl. 702/62

(57) ABSTRACT

Many households are increasingly installing systems for their own electricity supply from renewable energies, for example for economical or ecological reasons. If a household produces more electricity than it needs for its own use, it can feed the surplus amount of power into the electrical grid. In order to promote investment in corresponding systems, the payments for the power fed in are subsidized in many countries, with the result that comparatively high remuneration can be paid for the power fed in. Consequently, there is a great incentive to manipulate electricity meters for measuring the amount of power fed in. Hence, a system for detecting the amount of power fed in in a manner which is protected against manipulation can be provided, in which system the amount of power actually produced and that fed in can be balanced.

### CROSS-REFERENCE TO RELATED APPLICATIONS

This application is a U.S. National Stage Application of International Application No. PCT/EP2008/004774 filed Jun. 13, 2008. The contents of which are hereby incorporated by reference in their entirety.

### TECHNICAL FIELD

The invention relates to a system and a feed-in electricity meter for manipulation-protected detection of an amount of feed-in electricity.

### BACKGROUND

A growing number of households are installing equipment for supplying their own electricity locally, e.g. for economical or ecological reasons. If a household generates more electricity than it requires for its own use, it can feed the surplus amount of electricity into the electrical grid.

In its simplest form, this feed-in energy is measured by a conventional electricity meter, which runs backwards during the time when electricity is being fed into the electrical grid. During this time, the recorded energy consumption of the household is reduced by the amount of feed-in electricity. There are also electricity meters which can measure the amount of consumed electricity and the amount of feed-in electricity separately.

Provided suitable technical arrangements are made (e.g. grid synchronization), it is therefore fundamentally possible to feed locally produced electricity into the networks of energy supply companies when the local electricity production exceeds the local electricity requirement.

Renewable energies are typically converted into electrical power for this purpose, e.g. in the form of a photovoltaic or solar power system on the outside or roof of the house, a biogas power system or a wind power system. In order to encourage investment in corresponding systems, the payments for feed-in electricity are subsidized, so that comparatively high levels of remuneration can be claimed for the feed-in electricity. This is governed by the Renewable Energy Law (EEG) in Germany, for example.

Consequently, there is a considerable incentive to manipulate electricity meters for measuring the amount of feed-in electricity. For example, electricity that was not generated using renewable energies, but was obtained relatively cheaply via a public electricity supply grid, is fed into the grid for this purpose. An attempt is thus made to receive a high subsidized payment for the energy that is fed in.

Electricity meters today are protected against manipulation, in order to ensure that the amount of electricity detected by the electricity meter corresponds to the amount of electricity that is actually consumed or fed in. If the measured data is queried remotely (remote metering), the communication between electricity meter and query system of the energy supply company can be cryptographically protected. However, this does not prevent electricity that was obtained in a conventional manner from being fed in (and hence measured) by a user with fraudulent intention.

### SUMMARY

According to various embodiments, a system for manipulation-protected detection of an amount of feed-in electricity can be specified, in which it is possible to reconstruct a balance between the amount of electricity that is generated and that which is fed in.

According to an embodiment, a system for manipulation-protected detection of an amount of feed-in electricity, may comprise at least one electricity generating unit which features an integrated electricity meter for detecting an amount of electricity that is generated by the electricity generating unit, a feed-in electricity meter for detecting an amount of electricity that is fed in by the electricity generating unit, a transmission entity for transferring information about the detected generated amount of electricity to the feed-in electricity meter, wherein a manipulation-protected amount of feed-in electricity is determined by the feed-in electricity meter, in accordance with predefinable criteria, from the detected amount of generated electricity and the detected amount of feed-in electricity.

According to a further embodiment, the feed-in electricity meter can be read by a network operator via a remote query, information about the detected amount of generated electricity and the detected amount of feed-in electricity can be determined at the network operator in the context of the readout. According to a further embodiment, for the purpose of determining the manipulation-protected amount of feed-in electricity, the detected amount of generated electricity and the detected amount of feed-in electricity can be compared, taking into consideration any losses during energy transfer from the electricity generating unit to the feed-in electricity meter, and the detected amount of feed-in electricity can be corrected or controlled accordingly. According to a further embodiment, the information concerning the detected amount of generated electricity can be transferred by cryptographically protected means. According to a further embodiment, information for authenticating the electricity generating unit can be additionally transferred from the transfer entity to the feed-in electricity meter, the information authentication of the electricity generating unit is checked by the feed-in electricity meter. According to a further embodiment the transfer of information concerning the detected amount of generated electricity can be effected using wire-based means, in particular via Power Line Communication (PLC), or wirelessly. According to a further embodiment, an inverter unit can be provided for generating an alternating current from a direct current that is generated by the electricity generating entity.

According to another embodiment, a feed-in electricity meter for manipulation-protected detection of an amount of feed-in electricity, may comprise an entity for detecting an amount of electricity that is fed in from an electricity generating unit, a communication entity for receiving information concerning a generated amount of feed-in electricity from the electricity generating unit, wherein the feed-in electricity meter is configured to determine a manipulation-protected amount of feed-in electricity, in accordance with predefinable criteria, from the received amount of generated electricity and the detected amount of feed-in electricity.

According to a further embodiment of the feed-in electricity meter, the feed-in electricity meter can be configured for remote query by a network operator.

### BRIEF DESCRIPTION OF THE DRAWINGS

The present invention is explained in greater detail below on the basis of exemplary embodiments and with reference to the figures, in which:

FIG. 1 shows a schematic illustration of a possible embodiment of the system for manipulation-protected detection of an amount of feed-in electricity,

FIG. 2 shows a schematic illustration of a further possible embodiment of the system for manipulation-protected detection of an amount of feed-in electricity.

### DETAILED DESCRIPTION

According to various embodiments, a system for manipulation-protected detection of an amount of feed-in electricity comprises at least one electricity generating unit which features an integrated electricity meter for detecting an amount of electricity that is generated by the electricity generating unit. Furthermore, the system features a feed-in electricity meter for detecting an amount of electricity that is fed in by the electricity generating unit and a transmission entity for transferring information about the detected generated amount of electricity to the feed-in electricity meter. The feed-in electricity meter is configured in such a way that a manipulation-protected amount of feed-in electricity is determined, in accordance with predefinable criteria, from the received amount of generated electricity and the detected amount of feed-in electricity.

In order to prevent manipulation, the various embodiments provide for electricity meters which detect the amount of generated electricity to be integrated decentrally in the individual photovoltaic modules, for example. This information is then transferred to the centrally arranged feed-in electricity meter, such that a comparison can be made between an amount of feed-in electricity and an actual amount of generated electricity. Thus it is advantageously ensured that the electricity which has actually been generated in a subsidized way can be determined proportionally from the amount of feed-in electricity.

According to an embodiment, the feed-in electricity meter can be read remotely by a network operator via a remote query, wherein information about the detected amount of generated electricity and the detected amount of feed-in electricity are transmitted to the network operator in the context of the readout. In this way, the analysis can be performed by the network operator to whom the feed-in electricity is supplied. As part of this activity, provision can also be made for additionally transmitting a warning report, for example.

According to an embodiment, for the purpose of determining the manipulation-protected amount of feed-in electricity, the feed-in electricity meter compares the detected amounts of generated and feed-in electricity, taking into consideration any losses resulting from energy transfer, and corrects the detected amount of feed-in electricity accordingly. A consistency check between the amount of generated energy and the amount of feed-in energy is therefore advantageously performed. The efficiency or losses due to the energy transfer from the electricity generating unit to the feed-in electricity meter are taken into consideration in the context of such a consistency check. For example, a percentage reduction is therefore applied such that, in the case of an amount of generated electricity of 127 kWh and an efficiency of 80%, the detected amount of generated electricity is 127 kWh·0.8=101.6 kWh.

On the basis of this information, it is possible e.g. to limit the amount of feed-in electricity to the amount of electricity that is verifiably generated by photovoltaic modules. Further elements between the electricity generating units and the feed-in electricity meter, such as e.g. an inverter, result in further losses and can be taken into consideration accordingly when determining the detected amount of generated electricity.

According to a further embodiment, information for authenticating the electricity generating unit is additionally transferred from the transfer entity to the feed-in electricity meter, and the information for authenticating the electricity generating unit is checked by the feed-in electricity meter. In this way, a relationship is advantageously established between the individual electricity generating units and the feed-in electricity meter. The identities of the solar modules in a household can be entered in a list, for example. Only measured data that is received from the listed solar modules is then accepted. This can be managed via a protected administration interface, for example. The energy supply company, with which a feed-in contract has been agreed and which operates the feed-in electricity meter, can therefore configure the feed-in electricity meter in such a way that it only accepts and analyzes measured data from the configured solar modules, for example.

The feed-in electricity meter according to various embodiments for manipulation-protected detection of an amount of feed-in electricity features an entity for detecting an amount of feed-in electricity from an electricity generating unit and a communication entity for receiving information about a generated amount of feed-in electricity from the electricity generating unit. The feed-in electricity meter is configured such that, in accordance with predefinable criteria, a manipulation-protected amount of feed-in electricity can be determined from the received amount of generated electricity and the detected amount of feed-in electricity.

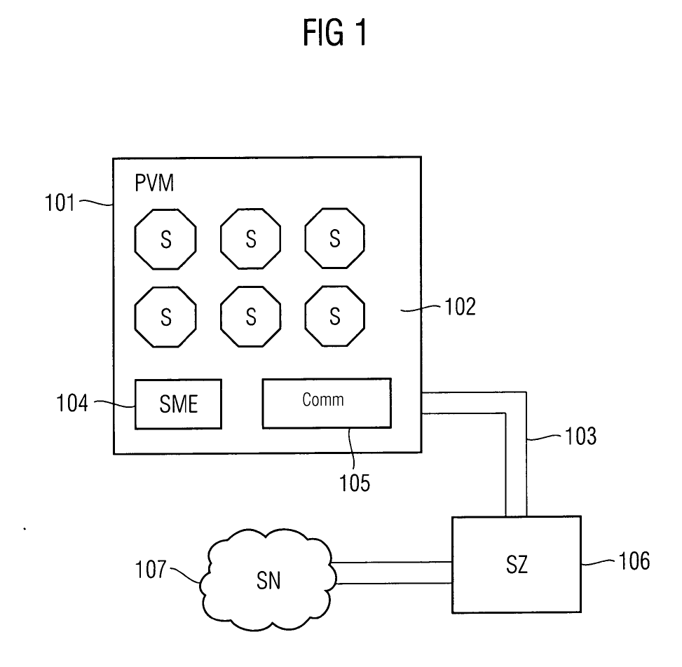

FIG. 1 shows a photovoltaic module 101 comprising a plurality of solar cells 102. The photovoltaic module 101 transfers the generated energy to the exterior via two electricity lines 103.

In addition, the photovoltaic module 101 has an integrated electricity meter 104, by means of which the amount of generated electricity is detected and stored.

In addition, the photovoltaic module 101 features a communication module 105, via which it is possible to query the current value of the amount of electricity, as measured by the integrated electricity meter 104.

Optionally or additionally, provision can also be made for a display device, on which the detected amount of electricity is displayed.

The communication takes place via a separate interface, e.g. serially (RS232, USB) or wirelessly (IEEE 802.15.4, ZigBee, WLAN). In an embodiment, the communication takes place via Power Line Communication, i.e. via electricity lines.

The electricity meter 104 preferably stores an identifier of the photovoltaic module 101, e.g. a serial number, and a cryptographic key. The cryptographic key is e.g. a symmetrical key for a symmetrical cryptographic method or a private key for an asymmetrical cryptographic method. The information that is provided in relation to the detected amount of generated electricity can then be additionally protected against manipulation by a cryptographic checksum (Message Authentication Code, digital signature).

The electricity that is generated by the photovoltaic module is fed into the electricity grid 207 of an energy supply company via a feed-in electricity meter 106.

Using Power Line Communication, information about the detected amount of generated electricity and an identifier of the photovoltaic module 101 are also transferred to the feed-in electricity meter 106 via the electricity lines 103.

The feed-in electricity meter 106 first checks the identity of the photovoltaic module 101, e.g. by means of comparison with a list of authorized photovoltaic modules. Measured data is only accepted from authorized photovoltaic modules. A received cryptographic checksum can be checked using the stored cryptographic key which is assigned to the photovoltaic module (symmetrical key for a symmetrical method, public key for an asymmetrical method). After successful checking, the electricity that was actually generated in a subsidized way is determined proportionally by the electricity meter 106 from the total amount of feed-in electricity, by comparing a detected amount of generated electricity and a detected amount of feed-in electricity.

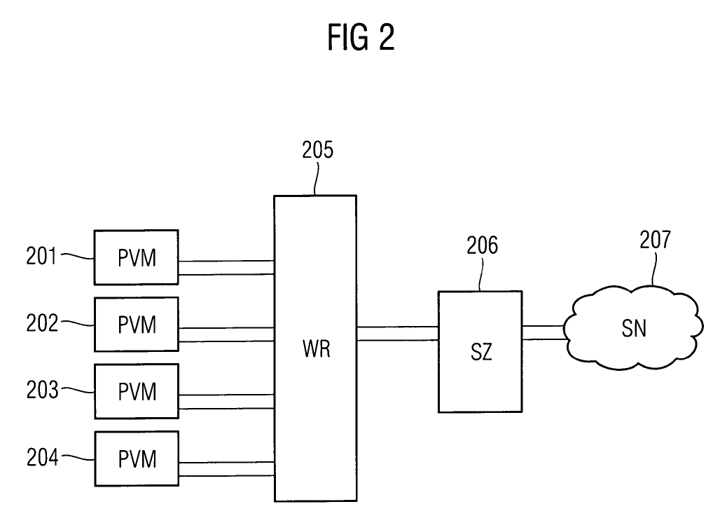

FIG. 2 shows an installation comprising four photovoltaic modules 201 to 204, each of which is configured as per FIG. 1.

The energy that is generated by the four photovoltaic modules 201 to 204 is routed to an A.C. current converter 205. This generates an alternating current, which is suitable for feeding into the grid of an energy supply company, from the direct current that is generated by the four photovoltaic modules 201 to 204.

The alternating current that is generated by the A.C current converter 205 is now fed into the electricity grid 207 of an energy supply company via an electricity meter 206.

The feed-in electricity meter 206 according to various embodiments is configured to receive the information transmitted from the communication module 105 of a photovoltaic module 201 to 204 concerning the detected amount of generated electricity.

If a consistency check is now required, for example, the electricity meter 206 can read out the current values for the amount of electricity from the photovoltaic modules 201 to 204, and compare them with the measured amount of feed-in electricity. Consideration is preferably given to the efficiency of the overall installation in this context, i.e. to the respective energy losses that occur in the photovoltaic modules 201 to 204 and the energy losses that occur in the A.C. current converter 205, for example.

According to an embodiment, the feeding in of electricity is stopped by the feed-in electricity meter 206 when the verifiably generated amount of electricity has already been fed in.

Alternatively, the consistency check can also be performed by the network operator, i.e. by transmitting the information about the detected amount of generated electricity and about the detected amount of feed-in electricity to the network operator.

In an alternative embodiment, the inverter 205 receives the information from the respective communication module 105 of a photovoltaic module 201 to 204 concerning the detected amount of generated electricity, measures the amount of electricity that has been supplied, and performs a consistency check by comparing the information with the measured amount of electricity that has been supplied. The inverter can additionally feature a communication module (not shown), by means of which it transfers information to the feed-in electricity meter 206. This information can be the result of a consistency check, or information which is aggregated from the information that has been transmitted by the respective communication module 105 of the photovoltaic modules 201 to 204, e.g. the total of the respective values of the amount of electricity, optionally reduced by energy losses that occur during the transfer of electricity and/or in the inverter 205.

What is claimed is:

1. A system for manipulation-protected detection of an amount of feed-in electricity, comprising
at least one electricity generating unit comprising an integrated electricity meter for detecting an amount of electricity that is generated by the electricity generating unit,
a feed-in electricity meter for detecting an amount of electricity that is fed in by the electricity generating unit,
a transmission entity for transferring information about the detected generated amount of electricity to the feed-in electricity meter,
wherein a manipulation-protected amount of feed-in electricity is determined by the feed-in electricity meter, in accordance with predefinable criteria, from the detected amount of generated electricity and the detected amount of feed-in electricity.

2. The system according to claim 1, wherein
the feed-in electricity meter can be read by a network operator via a remote query,
information about the detected amount of generated electricity and the detected amount of feed-in electricity is determined at the network operator in the context of the readout.

3. The system according to claim 1, wherein
for the purpose of determining the manipulation-protected amount of feed-in electricity, the detected amount of generated electricity and the detected amount of feed-in electricity are compared, taking into consideration any losses during energy transfer from the electricity generating unit to the feed-in electricity meter, and the detected amount of feed-in electricity is corrected or controlled accordingly.

4. The system according to claim 1, wherein
the information concerning the detected amount of generated electricity is transferred by cryptographically protected means.

5. The system according to claim 1, wherein
information for authenticating the electricity generating unit is additionally transferred from the transfer entity to the feed-in electricity meter,
the information authentication of the electricity generating unit is checked by the feed-in electricity meter.

6. The system according to claim 1, wherein
the transfer of information concerning the detected amount of generated electricity is effected using wire-based means or wirelessly.

7. The system according to claim 1, wherein
an inverter unit is provided for generating an alternating current from a direct current that is generated by the electricity generating entity.

8. A feed-in electricity meter for manipulation-protected detection of an amount of feed-in electricity, comprising
an entity for detecting an amount of electricity that is fed in from an electricity generating unit,
a communication entity for receiving information concerning a generated amount of feed-in electricity from the electricity generating unit,
wherein the feed-in electricity meter is configured to determine a manipulation-protected amount of feed-in electricity, in accordance with predefinable criteria, from the received amount of generated electricity and the detected amount of feed-in electricity.

9. The feed-in electricity meter according to claim 8, configured for remote query by a network operator.

10. A method for manipulation-protected detection of an amount of feed-in electricity provided by at least one electricity generating unit having an integrated electricity meter for detecting an amount of electricity that is generated by the electricity generating unit, the method comprising:
detecting by a feed-in electricity meter an amount of electricity that is fed in by the electricity generating unit,
transferring by a transmission entity information about the detected generated amount of electricity to the feed-in electricity meter,
determining a manipulation-protected amount of feed-in electricity by the feed-in electricity meter, in accordance with predefinable criteria, from the detected amount of generated electricity and the detected amount of feed-in electricity.

11. The method as claimed in claim 10, wherein the feed-in electricity meter can be read by a network operator via a remote query,
information about the detected amount of generated electricity and the detected amount of feed-in electricity is determined at the network operator in the context of the readout.

12. The method as claimed in claim 10, wherein
for the purpose of determining the manipulation-protected amount of feed-in electricity, the detected amount of generated electricity and the detected amount of feed-in electricity are . compared, taking into consideration any losses during energy transfer from the electricity generating unit to the feed-in electricity meter, and the detected amount of feed-in electricity is corrected or controlled accordingly.

13. The method as claimed in claim 10, wherein
the information concerning the detected amount of generated electricity is transferred by cryptographically protected means.

14. The method as claimed in claim 10, wherein
information for authenticating the electricity generating unit is additionally transferred from the transfer entity to the feed-in electricity meter,
the information authentication of the electricity generating unit is checked by the feed-in electricity meter.

15. The method as claimed in claim 10, wherein
the transfer of information concerning the detected amount of generated electricity is effected using wire-based means or wirelessly.

16. The method as claimed in claim 15, wherein the wire-based means are a Power Line Communication (PLC).

17. The method as claimed in claim 10, further comprising generating by an inverter unit an alternating current from a direct current that is generated by the electricity generating entity.

18. The system as claimed in claim 6, wherein the wire-based means are a Power Line Communication (PLC).
